(19) United States
(12) Patent Application Publication
(10) Pub. No.: US 2024/0139775 A1
(43) Pub. Date: May 2, 2024

(54) ULTRASONIC TRANSDUCER

(71) Applicant: TDK ELECTRONICS AG, München (DE)

(72) Inventors: Michael Gebhart, Linz (AT); Stefan Sax, Graz (AT); Amira Hedhili, Graz (AT); Martina Kreuzbichler, Graz (AT); Peter Lukan, Deutschlandsberg (AT); Johann Kreiter, Deutschlandsberg (AT); Johann Pichler, Breitenau Am Hovhlantsch (AT); Pierre Baumann, Graz (AT); Jens Mohrmann, Graz (AT)

(21) Appl. No.: 18/547,839

(22) PCT Filed: Feb. 10, 2022
(86) PCT No.: PCT/EP2022/053221

§ 371 Date: Aug. 24, 2023

(30) Foreign Application Priority Data
Feb. 26, 2021 (DE) 102021104697.1

(51) Int. Cl. B06B 1/06; H10N 30/02; H10N 30/88

(52) U.S. Cl. CPC B06B 1/0651; H10N 30/02; H10N 30/883

(57) ABSTRACT

The application relates to an ultrasonic transducer comprising a carrier with conductor traces and a piezoelectric element with electrodes, wherein the piezoelectric element has a contact side which is fixed on the carrier, and wherein the conductor traces and the electrodes are electrically coupled via the contact side of the element.

### CROSS-REFERENCE TO RELATED APPLICATIONS

This application is a U.S. National Stage of International Application No. PCT/EP2022/053221, filed Feb. 10, 2022, which claims the benefit of Germany Patent Application No. 102021104697.1, filed Feb. 26, 2021, both of which are incorporated herein by reference in their entireties.

The invention relates to an ultrasonic transducer and a method of manufacturing an ultrasonic transducer.

Ultrasonic transducers are generally used for distance measurement. In transmit mode, an ultrasonic signal is emitted as a burst from the ultrasonic transducer during distance measurement, which is partially reflected back after it hits an object. In receive mode, this reflected-back pulse is detected, allowing a travel time to be determined. Since the ultrasonic waves propagate in air but also in water with known sound velocities, the travel time can be used to calculate the distance to the reflected object.

Cars use distance measurement by ultrasound, for example, in parking assistance systems that inform the driver via a warning signal that the distance to a nearby object becomes small. The ultrasonic transducers are usually housed in the bumpers, which offer a relatively large amount of space for the installation of an ultrasonic transducer together with a housing and the necessary electronics.

The publication WO 2020/245064 A2 describes an ultrasonic transducer in which a piezo element and evaluation electronics are connected by means of wires.

The publication WO 2016/184604 A1 describes an ultrasonic transducer with a piezoelectric element whose electrodes cover opposite surfaces and side faces of the piezoelectric element.

Publication EP 2133156 B1 describes an ultrasonic transducer with a piezoelectric element, in which the piezoelectric element is glued inside the ultrasonic transducer via a side that has no electrodes.

New technological developments and applications such as drones or autonomous robots pose new challenges for an ultrasonic transducer suitable for distance measurement.

An ultrasonic transducer that is compact, robust, and inexpensive to manufacture is therefore desirable.

It is therefore an object of the present invention to provide an improved ultrasonic transducer and a suitable manufacturing method.

This task is at least partially solved by devices or methods according to the independent claims.

An ultrasonic transducer is described that includes a carrier with conductor traces and a piezoelectric element with electrodes. The piezoelectric element has a contact side that is attached to the carrier. The conductor traces of the carrier and the electrodes of the piezoelectric element are electrically coupled via the contact side of the element. In other words, the conductor traces of the carrier and the electrodes of the piezoelectric element are electrically coupled at the contact side of the element.

The contact side is the side of the piezoelectric element facing the carrier. The contact side can be a lower side of the piezoelectric element.

Electrical coupling between the electrodes and the contacts preferably eliminates the need for further components for electrical contacting of the piezoelectric element, in particular wires. In particular, electrodes and contacts can be electrically coupled directly. The structure of the ultrasonic transducer thus becomes more compact and robust, and a manufacturing process of the ultrasonic transducer is simplified and less expensive.

The carrier may perform the function of a membrane in the ultrasonic transducer. In particular, the carrier may be the bottom of a container of the ultrasonic transducer.

The piezoelectric element can be designed as a disk, i.e. as a geometric body whose height in a direction perpendicular to the contact side is significantly smaller than its other dimensions. In particular, the piezoelectric element can be designed as a flat cylinder. The diameter of the cylinder is significantly larger than the height of the cylinder. In further embodiments, the piezoelectric element may have any other shape, for example, any other rotationally symmetric shape, an elliptical shape, any n-cornered shape (polygonal shape; n=3, 4, 5, 6, . . . ) or a cubic shape.

The piezoelectric element comprises a piezoelectric material. The piezoelectric material may comprise a piezoelectric ceramic or a piezoelectric polymer.

In at least one embodiment, the electrodes are polarized differently during operation (in the operating state), for example positively and negatively polarized. Thereby, a voltage can be applied to the piezoelectric element via the electrodes.

In at least one embodiment, a voltage is applied between the electrodes during operation. The electrodes are arranged on the piezoelectric element such that a voltage is applied to the element via the electrodes.

All of the features described below may also apply to the ultrasonic transducer described previously.

Furthermore, an ultrasonic transducer is described which has a container with a bottom which is designed as a carrier for the piezoelectric element. Furthermore, the ultrasonic transducer comprises a wall and an installation opening. The installation opening can be closed with a lid. Electronics are integrated in the container or in the lid or in the container and in the lid. A contact side of a piezoelectric element is attached to the carrier. The ultrasonic transducer further comprises conductor traces that electrically connect electrodes of the piezoelectric element and connection points of the electronics.

In particular, the electronics can be integrated in the wall and in the lid or exclusively in the lid.

The ultrasonic transducer described may have all the features of the ultrasonic transducer described previously.

In particular, in at least one embodiment, the electrodes are polarized differently during operation (in the operating state), e.g. positively and negatively polarized. Thereby, a voltage can be applied to the piezoelectric element via the electrodes.

In at least one embodiment, a voltage is applied between the electrodes during operation. The electrodes are arranged on the piezoelectric element such that a voltage is applied to the element via the electrodes.

In transmit mode, the piezoelectric element can be excited, via an AC voltage applied by the electronics, to a pulse-like oscillation, in particular a burst-like oscillation, with a frequency of, for example, about 30 kHz to 100 kHz and a predetermined number of periods. Since the piezoelectric element is attached to the carrier, the carrier can resonate as a membrane and can emit an ultrasonic cone. When the ultrasonic cone hits an object or another obstacle, the ultrasonic cone can be reflected back partially. This reflected ultrasonic pulse may in turn hit the carrier or membrane and may induce a mechanical deflection in both the carrier and the piezoelectric element with the same frequency as the emitted pulse-like vibration. The mechanical deflection of the piezoelectric element material can induce a voltage change across the applied electrodes, which in turn can be read out by the electronics. The distance to the reflecting object can be calculated from the determined travel time of the ultrasonic pulse and the known speed of sound.

In one embodiment, the container may be pot-shaped, with the support acting as a membrane of the ultrasonic transducer and forming the bottom of a pot, while the wall forms a wall of the pot surrounding the installation opening that can be closed with the lid.

No further components for electrical contacting, such as wires, are required in the container between the piezoelectric element and the lid. Therefore, a cavity in the container between the carrier with the piezoelectric element and the lid can be filled by a damping element.

The damping element can fill the entire cavity. Provided it has a suitable shape, the damping element can already be hardened before it is inserted into the cavity.

The damping element can primarily serve to damp the ultrasonic vibrations from the piezoelectric element in the direction of the lid, but can also provide additional stabilization for the container. The most important material property for the damping element is the damping constant, which should be as large as possible at typical ultrasonic frequencies between 30 kHz and 100 kHz. Suitable materials are rubbers or foams. In particular, foams made of polymers, such as silicone, which have gas inclusions are suitable for the damping element.

The container can be made in one piece or in several pieces. For example, the container can be composed of a separate base element and a separate wall element.

The container can be essentially rotationally symmetrical or cubic. In the case of a rotationally symmetrical design, the container can be cylindrical, conical or frustoconical, for example. In this case, the container can correspond completely or partially to the basic geometric shape of the piezoelectric element, for example it can be round, elliptical or angular. An inner shape and/or an outer shape of the container can correspond to the basic shape of the piezoelectric element in this case, in particular the base element and/or the wall element can correspond to the basic shape of the piezoelectric element. The container has a cavity in the interior.

The inner shape and the outer shape of the container may be different within the same embodiment. For example, the surrounding wall of the cavity inside the container is cubically shaped and the outside of the container is cylindrically shaped. Further, for example, the container may be conical shaped on the inside and cylindrical shaped on the outside or cylindrical shaped on the inside and cubic shaped on the outside, etc. Other combinations of the inner and outer shapes are possible as desired.

Preferably, however, the inner and outer shapes are the same. For example, the container is cubic on the inside and cubic on the outside or cylindrical on the inside and cylindrical on the outside A particularly preferred design of the container is one that is conical or frustoconical on the inside and on the outside. This embodiment offers the advantage of simple production of the container, since due to the selected shape the container can be easily manufactured by means of pressing tools, for example by injection molding in the case of polymers or by deep drawing in the case of aluminum.

Furthermore, if the inner shape of the container is conical or frustoconical, the use of preformed and/or prehardened damping elements is particularly advantageous.

In the present case together with a suitable choice of the dimensions of the cavity in the container and of the damping element, it can be pre-determined in advance that the damping element always occupies the same volume of space within the container. This is in contrast to damping materials that are introduced in liquid form and are subsequently hardened, which can lead to different degrees of filling.

Furthermore, in contrast to the different depths at which cylindrical or cubic preformed damping elements are inserted into cylindrical or cubic containers, the setting depth of the damping element is determined in advance.

In addition, this design also offers the simple possibility of reproducibly setting a resonance chamber free of the damping element between the bottom of the container with the piezoelectric element applied and the end of the damping element opposite the bottom, which has a positive effect on the acoustic properties of the ultrasonic transducer.

The container may be made from a single material or from different materials. The container may include different sections made of different materials. The container may have different geometric shapes in different sections.

The container may be made of an electrically conductive material such as aluminum or an aluminum alloy. The container can be made of an electrically non-conductive material such as an electrically non-conductive polymer, for example LCP (Liquid Crystal Polymers).

If the container is made of an electrically conductive material such as aluminum, the container can be coated with an insulation layer on its surface. If the container is made of aluminum, an aluminum oxide layer, for example an anodised layer, can be formed as the insulation layer.

In one embodiment, if the container is made of an electrically non-conductive material, the container may have means interconnected with the electronics to provide sufficient shielding from radiated electromagnetic interference in the form of Faraday shielding despite the non-conductive container material.

For example, there may be internal electrode structures or metal meshes such as copper meshes in the container, preferably on the inside of the container, which are suitably connected to ground with the electronics. The metal meshes preferably cover the entire inside of the container.

Other possible embodiments for Faraday shielding include the application of a metallic coating to the inside and/or outside of the container (e.g., by sputtering, electroplating, etc.) or a conductive paint.

In addition, as an alternative or supplement to the Faraday shielding, a mechanical protective coating can be applied to the outside of the container, e.g. to reduce or prevent mechanical wear of the metallic coating during everyday operation of the ultrasonic transducer and thus to increase the service life of the metallic coating and thus of the ultrasonic transducer or to ensure trouble-free operation. The mechanical protective coating preferably covers the entire outside of the container.

If a metallic coating for Faraday shielding is applied only to the outside of the container, the necessary electrical contacting of the Faraday shielding to the electronics can, in one embodiment, be made as through hole, e.g. in the form of a via, through the container wall to the conductor traces inside the container. In this way, the ultrasonic transducer can be kept completely closed and no particularly sensitive over contacting via the narrow top edge around the installation opening of the container is necessary.

The piezoelectric element is arranged inside the container with its contact side on the carrier.

In addition, the ultrasonic transducer has the lid that closes the container. The electronics are integrated into the lid and are designed to control and read out the piezoelectric element. The integration of the electronics in the lid makes the ultrasonic transducer extremely compact.

By integrating the electronics in the lid, it is not necessary to build the ultrasonic transducer in an external housing in which the electronics are installed. By combining the function of a sound-emitting container with the function of a sensor housing, the present ultrasonic transducer can be made compact. In addition, costs can be saved in production, since additional electrical and mechanical interfaces are not required and the assembly of ultrasonic transducer and sensor housing can be dispensed with.

Alternatively or in addition, the electronics can also be provided completely or partially in the container, in particular in and/or on the wall.

In one embodiment of the ultrasonic transducer described, the conductor traces and the electrodes are electrically coupled via the contact side of the piezoelectric element.

In one embodiment, two electrodes are applied to the contact side of the piezoelectric element, which are electrically coupled to two contacts on the carrier of the container. In each case, one of the two electrodes is coupled to a corresponding contact.

In one embodiment, the contacts on the container carrier are electrically coupled to the corresponding electrical conductor traces. The contacts on the carrier of the container and the respective corresponding electrical conductor traces can in particular each represent a directly connected, uniform element.

The electrodes comprise electrically conductive materials such as copper, silver, nickel or chromium. The electrodes can be applied, for example, by sputtering or by printing, such as screen printing. Alternatively, the electrodes may be formed by depositing a conductive polymer.

In one embodiment, the lid can be fixed to the container by means of an electrically conductive lid adhesive. By means of the same electrically conductive lid adhesive, the electronics can be electrically contacted with the conductor traces.

The conductor traces comprise an electrically conductive material such as copper, silver, nickel or chromium. The conductor traces can be applied, for example, by sputtering or by printing, such as screen printing. Alternatively, the conductor traces may be formed by applying a conductive polymer.

In a preferred embodiment, the electrodes on the piezoelectric element and the connection points of the electronics are electrically connected exclusively by the conductor traces.

Further components for electrical contacting, such as wires, are not provided. The electronics and the piezoelectric element are therefore electrically connected without wires.

In at least one embodiment, the electrodes make electrical contact with the conductor traces.

For this purpose, the electrodes make electrical contact with the contacts of the conductor traces on the carrier. The electrodes and the contacts are in direct electrical contact with each other. The advantage of this arrangement is a secure and stable electrical connection between the electrodes and the contacts on the carrier, or the bottom of the container.

In at least one embodiment, the electrodes and the contacts of the conductor traces are contacted with each other without gaps. Advantageous in this embodiment are the compact arrangement and a stable electrical connection.

In one embodiment, the electrodes include a first electrode and a second electrode.

In at least one embodiment, the first electrode is arranged flat on the contact side of the piezoelectric element. The first electrode can cover a large part of the contact side.

In at least one embodiment, preferably in the same embodiment, a substantial portion of the second electrode is deposited on a side of the piezoelectric element opposite to the contact side. This side is hereinafter referred to as the upper side of the piezoelectric element. In addition to the part on the upper side of the piezoelectric element, other parts of the second electrode are arranged on a side surface and on the contact side of the piezoelectric element. The described electrode parts of the second electrode are interconnected, in particular they are in direct electrical contact with each other or form a uniform electrical contact area.

The described arrangement of the second electrode enables contacting of the two electrodes from the same side, preferably from the side in which the contact side of the piezoelectric element points.

The electrical contacting of the piezoelectric element thus takes place on the same side on which the piezoelectric element is mechanically attached to an inner side of the carrier. The inner side of the carrier is the side of the carrier that is facing towards the interior of the container. The inner side of the carrier faces the contact side of the piezoelectric element.

This simplifies the design and manufacturing process of the ultrasonic transducer.

In one embodiment, the contact side of the piezoelectric element is attached to the carrier by means of a carrier adhesive. The carrier adhesive is thus applied between the contact side of the piezoelectric element and the carrier.

The carrier adhesive allows the piezoelectric element to be attached to the carrier easily and in a compact manner. The carrier adhesive can be applied as a continuous adhesive connection in the form of an adhesive layer between the piezoelectric element and the carrier.

In at least one embodiment, the carrier adhesive is electrically non-conductive or insulating. The carrier adhesive between the contact side of the piezoelectric element and in this case the carrier is then used exclusively for mechanical fixation of the piezoelectric element.

By selecting a non-conductive carrier adhesive, a short circuit between the various electrodes on the contact side of the piezoelectric element can be avoided. The adhesive connection then also acts as an insulator between the electrodes.

In one embodiment, the electrodes and the conductor traces each have a rough surface. In this case, the electrodes and the conductor traces are spaced such that the electrodes and the conductor traces are in direct contact, in particular electrical contact. In particular, the electrodes are in contact with corresponding contacts of the conductor traces on the carrier.

In this embodiment, the contact side of the piezoelectric element including the electrodes and the inner side of the carrier opposite the contact side including the contacts of the conductor traces may be mechanically connected by means of an adhesive connection arranged therebetween.

Due to the given surface roughness of the electrodes and the contacts of the conductor traces, the electrodes and the contacts are in direct contact with each other at individual points if the adhesive connection is sufficiently thin at contact points where there are pronounced elevations on the surfaces of the electrodes or the contacts.

That is, contact points are formed where there is no carrier adhesive between an elevation on the surface of one of the electrodes and a corresponding contact or an elevation on the surface of a contact and a corresponding electrode.

Sufficient surface roughness of the electrodes or the contacts of the conductor traces and a suitably selected distance between the electrodes and the conductor tracesthus ensure adequate electrical contact between the electrodes and the conductor traces.

In other words, the electrical connection between the piezoelectric element and the conductor traces of the container is made by direct multiple point contact. Due to the naturally existing roughness of the opposing surfaces, the surfaces of the two electrodes on the one hand and the contacts of the carrier on the other hand, there are local points of direct contact between electrodes and conductor traces. These contacts allow good electrical conduction between electrodes and conductor traces.

In the case of surfaces whose natural roughness is not sufficiently high, the natural roughness can be artificially increased. For example, the natural roughness can be increased by using suitable technical processes, in particular the natural roughness can be increased by means of a laser ablation process.

In the above case, the carrier adhesive itself is not involved in electrical contacting.

At the same time, a higher surface roughness increases the available contact area between the piezoelectric element and the carrier, so that the strength and durability of the mechanical connection, especially the adhesive connection, and the electrical connection of the element and the container can be improved.

In one embodiment, the electrodes and the conductor trace contacts are each exposed to their surroundings. That is, on the one hand, the entire electrodes or at least sections of the electrodes protrude on the contact side of the piezoelectric element. This effect can be achieved simply by applying the electrodes to the contact side. To enhance the effect, the electrodes can be additionally reinforced.

On the other hand, the entire contacts of the conductor traces or sections of the contacts on the inside of the carrier protrude. This effect can be achieved simply by applying the contacts. To enhance the effect, the contacts can be additionally reinforced.

The electrodes and the contacts can generally be applied and/or reinforced, for example, by sputtering or electroplating. The electrodes and the contacts comprise a good electrically conductive material, preferably a metal or a metal alloy, such as copper, silver, nickel or chromium, or an electrically conductive polymer.

Since the contacts and the electrodes are exposed to their respective environments, they can be in mutual direct contact, while a non-conductive adhesive connection is formed between the remaining contact side of the piezoelectric layer and the remaining inner side of the carrier for mechanical connection.

This last described embodiment thus ensures sufficient electrical contact between the electrodes and the contacts.

In another embodiment, the electrodes and the conductor traces are capacitively coupled.

In this embodiment, the electrodes and the conductor trace contacts are not in direct contact with each other. For example, the contacts may be patterned in the carrier such that they are not exposed at a surface of the carrier.

Alternatively or additionally, an electrically insulation layer can be arranged between the electrodes and the conductor traces. The additional insulation layer can consist of a non-conductive material, in particular an organic non-conductor. For example, the organic non-conductor may be applied in the form of a lacquer. Particularly preferably, the insulation layer can be formed by the non-conductive carrier adhesive itself.

The described embodiment has the advantage that the electrodes and the contacts form a capacitor, which can replace an additional capacitor component in the electronics. Thus, the design of the ultrasonic transducer, especially the electronics, and the manufacturing process can be simplified.

In one embodiment, the carrier adhesive is anisotropically electrically conductive. The carrier adhesive is electrically conductive in a direction perpendicular to the contact side of the piezoelectric element and the inner side of the carrier. Thus, the carrier adhesive acts as an electrical conductor between the electrodes and the associated contacts.

At the same time, the carrier adhesive acts as an electrical insulator in any direction parallel to the contact side of the piezoelectric element. Thus, similar to a non-conductive carrier adhesive, the carrier adhesive acts as an insulator between different electrodes, in particular between electrodes with different polarity during operation (in the operating state) and/or contacts with different polarity.

Such an anisotropic, electrically conductive carrier adhesive ensures stable electrical contacting between the electrodes and the conductor trace contacts, while preventing unwanted electrical contacting or short circuits.

In at least one embodiment, the contacts of the conductor traces are applied to the inner side of the carrier. The inner side of the carrier faces the contact side of the piezoelectric element. This enables direct electrical contacting of the contacts and the electrodes on the contact side of the piezoelectric element. This can significantly simplify the design of the ultrasonic transducer.

In one embodiment, the conductor trace contacts are patterned in the carrier so that they are not exposed at a surface. This allows, for example, the formation of a capacitor between the contacts and the electrodes as described above.

The container also has conductor traces, as described above, which electrically connect the electrodes of the piezoelectric element and the electronics. The electronics have connection points at which electrical contact is made between the electronics and the conductor traces. Preferably, the electronics has two connection points, each of which serves to make electrical contact with a conductor trace.

The design of the conductor traces means that there is no need for electrical connection by wires.

In one embodiment, the conductor traces are arranged on the inner surface of the container. The conductor traces are applied to the inner surface of the container in the form of metal tracks, for example. Materials with good electrical conductivity, such as copper, silver, nickel or chromium, are suitable for this purpose. The conductor traces are applied by sputtering, for example. In the case of a container made of electrically conductive material, an insulation layer is formed on the surface of the container between the conductor traces and the container.

The conductor traces extend from the contacts of the carrier to the section of the wall of the container to which the lid with the electronics is attached. The electronics are in electrical contact with the conductor traces.

In one embodiment, the conductor traces are integrated inside the container. The conductor traces can be structured in the wall of the container.

If the container itself is electrically conductive, the container can be used as a first conductor track. For this purpose, the insulation layer is interrupted at a first contact point, the point of contact to the first electrode, and a second contact point, the point of contact to a connection point of the electronics.

A second conductor track connecting the second electrode to the electronics may then be applied to the insulation layer on the inside of the container.

If the container itself is not electrically conductive, electrically conductive structures can be formed as inner conductor traces in the container. For direct electrical contacting, these inner conductor tracks are exposed at the first contact point and the second contact point or extend there to the inner surface of the container.

In one embodiment, the conductor traces and electronics are electrically connected by means of an electrically conductive lid adhesive.

At least at the second connection point of the conductor traces, which is formed opposite a connection point of the electronics, the lid adhesive is applied for this purpose, with the aid of which the electronics are electrically contacted.

The carrier adhesive and the lid adhesive are preferably two different adhesives, each with optimized properties related to their application.

In at least one embodiment, the lid is also mechanically attached to the container by means of the electrically conductive lid adhesive. The lid adhesive thus serves for mechanical fastening and electrical contacting of the lid.

In a further embodiment, the lid is mechanically attached to the container by means of an elastic, non-conductive adhesive. The lid adhesive is then used exclusively for electrical contacting of the lid.

Furthermore, an ultrasonic transducer is described which has a container with an installation opening which can be closed with a lid with integrated electronics. The lid can be bonded to the container by means of an electrically conductive lid adhesive and the electronics can be electrically contacted with conductor traces of the container by means of the electrically conductive lid adhesive.

In other respects, the ultrasonic transducer described may have all of the features of the ultrasonic transducers described previously.

Furthermore, a method for manufacturing an ultrasonic transducer is described. The method comprises several steps.

In step a, a container which can be closed with a lid and has an installation opening is provided. Electronics are integrated in the lid. The container also comprises a bottom in the form of a carrier and conductor traces. Alternatively or additionally, the electronics may be provided in whole or in part in the container.

In step b, a piezoelectric element in the container is attached to the carrier. The piezoelectric element is attached in such a way that electrodes arranged on the piezoelectric element are electrically connected to connection points of the electronics via the conductor traces.

Step b of the method may further comprise the following substeps:

In a sub-step, the piezoelectric element is attached so that the electrodes are electrically coupled to the conductor traces.

In a further sub-step, the installation opening is closed with the lid. Here, the connection points of the electronics are electrically coupled to the conductor traces in such a way that the electronics are electrically connected to the electrodes without wires.

In an alternative embodiment in which the electronics are already provided entirely within the container, the electrodes and the electronics are already electrically connected wirelessly before the lid is closed.

In one embodiment, the method may further comprise a step of inserting a damping element between the piezoelectric element and the lid. The damping element fills the container.

The ultrasonic transducer may further include any of the features of the ultrasonic transducers previously described.

In one embodiment of the method, a container is provided in one step. The container has an installation opening, a bottom that acts as a carrier, and a wall. Contacts of conductor traces are provided on an inner side of the carrier. The inner side of the carrier is the side facing into the interior of the container. In addition, electronics may be present in whole or in part in the container.

In a further step, a carrier adhesive is applied to the inside of the carrier.

The carrier adhesive preferably comprises a thermosetting adhesive, such as a thermosetting epoxy adhesive.

In a further step, a contact side of a piezoelectric element on which two electrodes are pronounced is applied to the carrier adhesive. In an alternative embodiment, the carrier adhesive is applied to the contact side of the piezoelectric element.

In a further step, the piezoelectric element is pressed onto the inside of the carrier so that the two electrodes are in direct contact with the contacts of the carrier. The carrier adhesive is then cured.

Direct contact can be achieved, for example, by a sufficiently high surface roughness of the contacts and the electrodes. The carrier adhesive is partially displaced during pressing, so that elevations on the surfaces of the contacts and electrodes are in direct contact with each other.

A high surface roughness further results in an advantageous larger surface area of the electrodes and the contacts.

Direct contact can further be achieved by raised sections of the electrodes and contacts compared to their surroundings. When the carrier adhesive is pressed on, it is displaced so that the raised surfaces are in direct contact with each other, while an adhesive connection is formed between non-raised surfaces. In one embodiment of the process, a force of at least 0.3 N is applied during pressing. Preferably, a force of at least 0.3 N and at most 3 N is applied.

During curing, the carrier adhesive can contract so that the contact between the two electrodes and the corresponding contacts is intensified.

The curing of the carrier adhesive can, for example, be thermal or UV-induced.

In a further step, an electrically insulation layer can be applied to the inside of the carrier or to the contact side of the piezoelectric element before the piezoelectric element is applied. The insulation layer covers at least the contacts and/or the electrodes so that they are no longer in electrical contact.

The application of the insulation layer, which comprises a non-conductive material, can be performed alternatively or in addition to the application of the carrier adhesive. The insulation layer can also comprise the carrier adhesive itself. A capacitance of the now purely capacitive, i.e. non-ohmic, contact between the electrodes and the conductor traces can be adjusted by this.

In the following, embodiments of the invention are explained with reference to figures. The invention is not limited to the exemplary embodiments and their features.

The figures show:

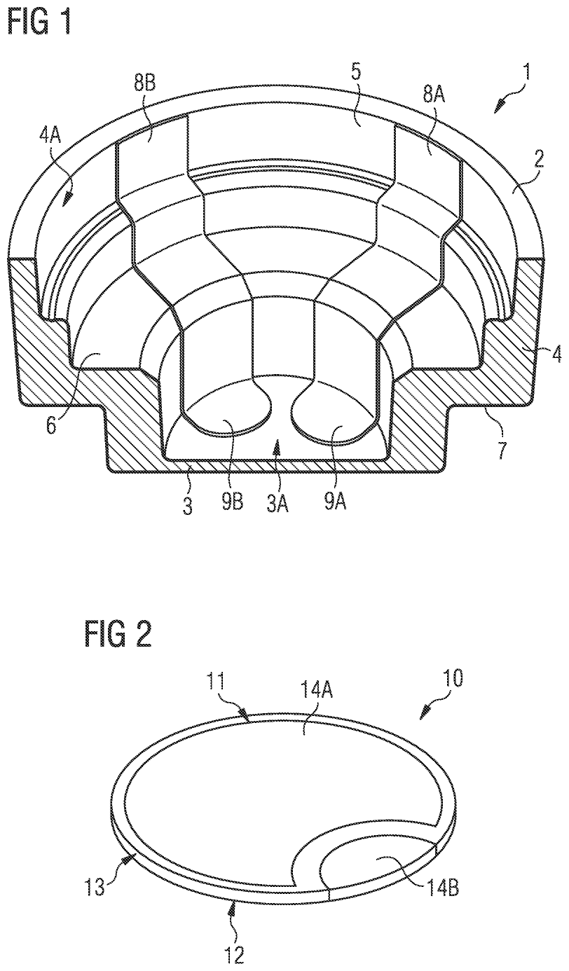

FIG. 1: Perspective sectional view of a container according to a first embodiment of the ultrasonic transducer.

FIG. 2: Perspective top view of a piezoelectric element according to the first embodiment of the ultrasonic transducer.

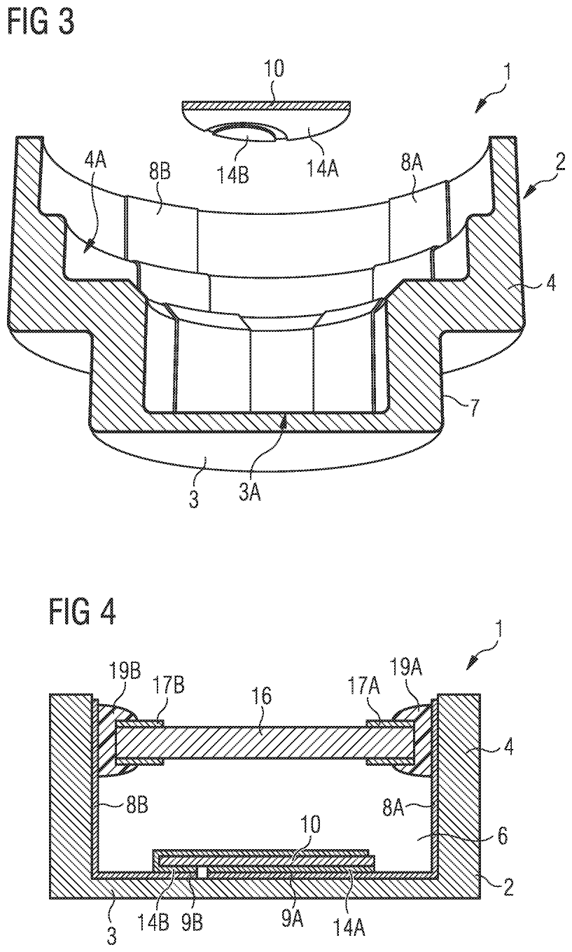

FIG. 3: Perspective sectional view of the container and the piezoelectric element of the first embodiment of the ultrasonic transducer.

FIG. 4: schematic sectional view of the first embodiment of the ultrasonic transducer in the assembled state.

FIG. 5: Detailed illustration of a contact area with groove-shaped cutouts and elevations.

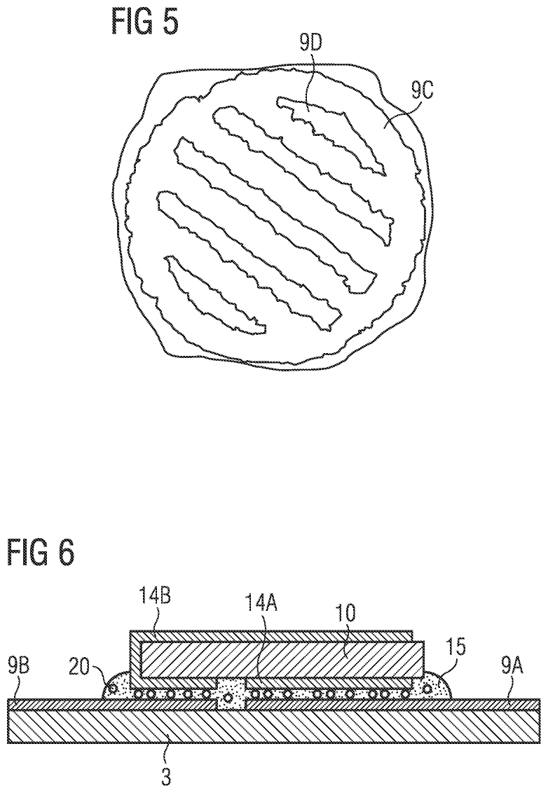

FIG. 6: Sectional view of a piezoelectric element and a carrier of a second embodiment.

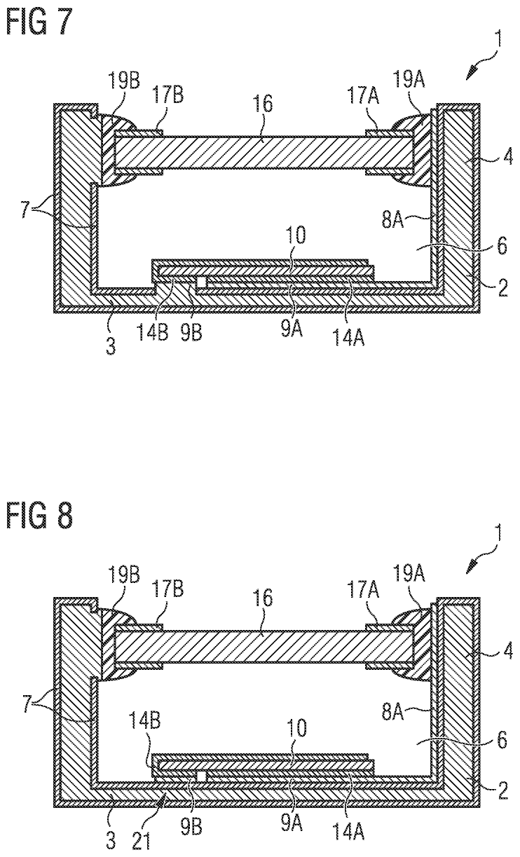

FIG. 7: schematic sectional view of the fourth embodiment of the ultrasonic transducer in the assembled state.

FIG. 8: schematic sectional view of the fifth embodiment of the ultrasonic transducer in the assembled state.

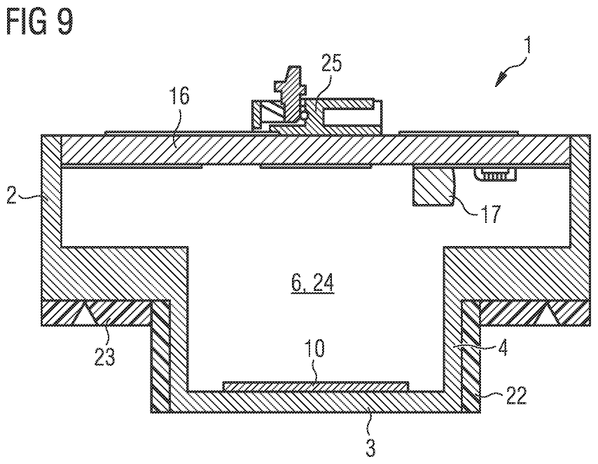

FIG. 9: detailed cross-sectional view of an assembled ultrasonic transducer.

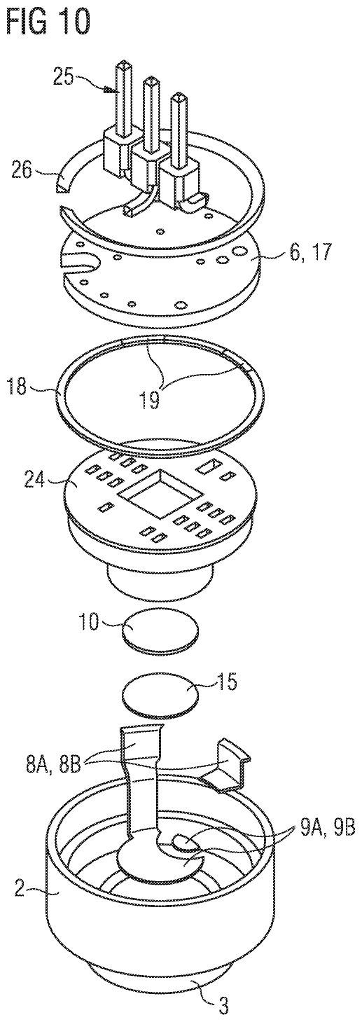

FIG. 10: detailed exploded view of an assembled ultrasonic transducer.

FIG. 1 shows a section through a container 2 of a first embodiment of an ultrasonic transducer 1.

In the present case, the container 2 is made in one piece. The container 2 comprises a support 3 corresponding to a bottom 3 of the container 2, a wall 4 and an opening 5 on its upper side. The support 3 serves as a membrane of the ultrasonic transducer 1. The container 2 has a rotationally symmetrical shape corresponding substantially to a cylinder. The carrier 3 is circular in shape and forms the base of the cylinder. The wall 4 comprises several cylinder sections of different diameters, which are arranged one above the other in a step-like manner. The diameter of the cylinder section adjacent to the carrier 3 is the smallest. The diameter of the cylinder section adjacent to the opening 5 is the largest.

The number of cylinder sections can vary depending on the application and technical requirements. For example, the wall 4 can comprise exactly one cylinder section.

In further, not shown, embodiments, the container 2 may take any other shape. Examples of further shapes of the container 2 are a conical shape or a cubic shape.

The container 2 has a cavity 6 on the inside. The cavity 6 is bounded at the bottom by the support 3 and at the sides by the wall 4. The cavity 6 is open at the top because the container 2 has the opening 5 there.

The surfaces of the carrier 3 and the wall 4 that face toward the cavity 6 inside the container 2 are referred to as the inner surfaces. The carrier 3 has an inner side of the carrier 3A and the wall 4 has an inner side of the wall 4A.

Accordingly, the outwardly facing surfaces of the container 2 are referred to as the outer surfaces.

In the first embodiment, the container 2 comprises an electrically conductive material. The electrically conductive material is, for example, aluminum or an aluminum alloy. In further examples, the container 2 may comprise further electrically conductive or electrically non-conductive materials.

In the present embodiment, the container 2 is therefore electrically conductive. The surfaces of the electrically conductive container 2 are coated with an insulation layer 7. If the container is made of aluminum, for example, this can be oxidized so that an electrically insulating anodised layer is formed. The electrically insulating anodised layer preferably has a thickness of between 5 and 25 μm.

The insulation layer 7 completely covers both the inner sides and the outer sides of the container 2.

Two separate, electrically conductive conductor traces 8A and 8B are applied to the inside of the container 2. The conductor traces extend from contact areas 9A and 9B on the inner side of the carrier 3A over the inner side of the wall 4A to the opening 5 of the container 2.

In another embodiment, not shown, the conductor traces 8A and 8B do not extend to the opening 5 of the container 2. In this case, the conductor traces 8A and 8B extend over only a portion of the inner side of the wall 4A in the direction of the opening 5 and terminate, for example, at any point on the inner side of the wall or at a step between the of cylinder sections.

The conductor traces 8A and 8B and the contact areas 9A and 9B comprise an electrically conductive material such as copper, silver, nickel or chromium. The conductor traces 8A and 8B or the contact areas 9A and 9B can be applied by sputtering or by printing, for example screen printing. Alternatively, the conductor traces 8A and 8B or the contact areas 9A and 9B can be formed by applying a conductive polymer. The contact areas 9A and 9B may additionally be reinforced with conductive material.

FIG. 2 shows a piezoelectric element 10 of the first embodiment of the ultrasonic transducer 1.

The piezoelectric element 10 is designed as a disk, or more precisely as a flat cylinder. The diameter of the cylinder is significantly larger than the height of the cylinder. The piezoelectric element 10 has a lower side 11, an upper side 12 and a side surface 13.

In further, not shown, embodiments, the piezoelectric element 10 may have any other shape, for example, another rotationally symmetric shape, an elliptical shape, an n-cornered shape, or a cubic shape.

The lower side 11 is the contact side of the piezoelectric element 10, which is applied to the inner side of the carrier 3A when installed, points upward in FIG. 2 for clarity.

The piezoelectric element includes a piezoelectric material.

A first electrode 14A is applied to the lower side 11. The first electrode 14A is applied exclusively to the lower side 11. In the first exemplary embodiment, the first electrode 14A covers a large part of the lower side 11.

A second electrode 14B is applied to the upper side 12 of the piezoelectric element in a planar manner. In the first embodiment, the second electrode 14B covers a large part of the upper side 12.

The second electrode 14B further extends over the side surface 13 and the lower side 11, with the electrode 14B being formed contiguously. The first electrode 14A and the second electrode 14B are formed spaced apart and are not in contact with each other. Rather, an insulation gap is formed on the lower side 11 between the two electrodes 14A and 14B.

The electrodes 14A and 14B comprise electrically conductive materials such as copper, silver, nickel or chromium. The electrodes 14A and 14B can be applied, for example, by sputtering or by printing, preferably by screen printing.

FIG. 3 shows how the piezoelectric element 10 is inserted into the container 2. The lower side 11 of the piezoelectric element 10 is applied to the inner side of the carrier 3A in such a way that the first electrode 14A is in direct contact with the first contact area 9A and thus with the first conductor track 8A and that the second electrode 14B is in direct contact with the second contact area 9B and thus with the second conductor track 8B. There is no contact between the first electrode 14A and the second contact area 9B or the second conductor track 8B, and there is no contact between the second electrode 14B and the first contact area 9A or the first conductor track 8A.

FIG. 4 shows the ultrasonic transducer 1 according to the first embodiment in the assembled state.

The piezoelectric element 10 is arranged in the container 2 as described above. In the assembled state, the piezoelectric element 10 is attached to the carrier 3 by means of an adhesive connection not explicitly shown in FIG. 4. The adhesive connection is applied between the lower side 11 of the piezoelectric element 10 and the opposite section of the inner side of the carrier 3A.

The adhesive connection is electrically non-conductive. In the first embodiment, the adhesive connection comprises a thermally curing epoxy adhesive that is electrically non-conductive. In further embodiments, the adhesive connection may comprise other adhesives that are electrically non-conductive, for example UV-curing adhesives.

The adhesive connection may have non-conductive particles or fillers. These particles or fillers have diameters of less than 0.3 μm, for example 0.2 μm. Preferably, the adhesive layer has even smaller particles. Particularly preferably, the adhesive layer is completely free of particles or fillers.

Electrical contact between the electrodes 14A and 14B and the contact areas 9A and 9B is created by their surface roughness. If the surface roughness is sufficiently high, individual direct contacts are formed between elevations on the surface of electrodes 14A and 14B and elevations on the surface of contact areas 9A and 9B, which ensure electrical contacting. There is no adhesive connection between the electrodes 14A and 14B and the contact areas 9A and 9B at the points of electrical contact.

Such sufficient surface roughness is achieved, for example, at an average roughness Ra of 0.53 μm, and a roughness depth Rz of 3.4 μm of said surfaces.

Since the adhesive is electrically non-conductive, the adhesive connection acts as an electrical insulator, in particular as an insulator between the first electrode 14A and the second electrode 14B or the first contact area 9A and the second contact area 9B.

Furthermore, the adhesive connection protects the electrodes and the contact areas from environmental influences, for example from oxidation, so that the service life of the ultrasonic transducer 1 is increased.

The opening 5 of the container 2 is closed with a lid 16. Electronics 17 are integrated in the lid 16 and are designed to control and read out the piezoelectric element 10.

In the present example, the lid 16 is mechanically attached to the wall 4 by an annular, elastic adhesive connection 18. The annular, elastic adhesive connection 18 is not electrically conductive. The annular, elastic adhesive connection 18 seals the container 2 between the wall 4 and the lid 5 so that the cavity 6 is completely enclosed.

The annular elastic adhesive connection 18 comprises, for example, a non-electrically conductive silicone adhesive.

In addition, two electrically conductive elastic adhesive connections 19 are applied between the electronics 17 and the wall 4 to electrically connect the connection points of the electronics 17A and 17B and the conductor traces 8A and 8B. A first electrically conductive elastic adhesive connection 19A electrically connects a first connection point 17A and the conductor track 8A. A second electrically conductive elastic adhesive connection 19B electrically connects a second connection point 17B and the conductor track 8B.

For example, the electrically conductive elastic adhesive connections 19A and 19B comprise a conductive silicone adhesive. The electrically conductive elastic adhesive connections 19A and 19B have, for example, a resistivity between 1×10⁻³ and 3×10⁻² Ohm·cm.

The use of an elastic adhesive for the adhesive connections 18 and 19, ensures that, on the one hand, with respect to the adhesive connections 19A and 19B, a reliable electrical connection is established and, on the other hand, that vibrations of the container 2 are not transmitted to the printed circuit board or are transmitted only at a weakened level, which otherwise could lead, for example, to unwanted sound radiation in the rearward direction.

In the present exemplary embodiment, the cavity 6 is hollow. Such an embodiment simplifies the construction of the ultrasonic transducer 1. In further exemplary embodiments, which are not shown here, the cavity 6 can be filled with an insulating material. Since the cavity 6 does not have any other interfering internals, such as wires, the insulating material can be preformed and precured. The preformed insulating material can then simply be inserted into the cavity.

In an alternative embodiment of the first embodiment, specific areas of the contact areas 9A/9B or the electrodes 14A/14B are roughened. The roughening can be performed by means of laser irradiation. Thus, contact areas in the form of elevations on the surface of the electrodes 14A and 14B and elevations on the surface of the contact areas 9A and 9B can be selectively formed. The contact areas may form a predetermined pattern. For example, as shown in FIG. 5, groove-shaped recesses 9C can be formed by laser irradiation, between which parallel, elongated elevations 9D are formed.

In the following, a second exemplary embodiment of the ultrasonic transducer 1 is described which is not explicitly shown in the drawings. The second embodiment of the ultrasonic transducer 1 is mainly identical to the first embodiment of the first embodiment of the ultrasonic transducer 1. Identical features of the two embodiments are not described again to avoid repetition. Differences between the two embodiments will be described below.

FIG. 6 shows a piezoelectric element 10 and a carrier 3 of the second embodiment. As in the first embodiment, a lower side 11 of the piezoelectric element 10 is bonded to the inner side of the carrier 3A by means of an adhesive connection 15.

In contrast to the first embodiment, the adhesive connection in the second embodiment is anisotropically electrically conductive. The adhesive connection 15 is electrically conductive only in a direction perpendicular to the lower side 11 and perpendicular to the inner side of the carrier 3A. In any direction parallel to the lower side 11 or parallel to the inner side of the carrier 3A, the adhesive connection 15 is electrically insulating.

Thus, the adhesive connection 15 has an electrically insulating effect between the first electrode 14A and the second electrode 14B. Furthermore, the adhesive connection 15 has an electrically insulating effect between the first contact area 9A and the second contact area 9B. In contrast, between the first electrode 14A and the first contact area 9A, the adhesive connection 15 has an electrically conductive effect. Likewise, the adhesive connection 15 has an electrically conductive effect between the second contact area 9B and the second electrode 14B.

For example, the adhesive connection 15 includes an anisotropic, electrically conductive adhesive based on a non-conductive epoxy or acrylate matrix that includes a small amount of at least partially conductive or conductively coated particles 20.

In the following, a third exemplary embodiment of the ultrasonic transducer 1 is described that is not explicitly shown in the drawings. The third exemplary embodiment of the ultrasonic transducer 1 is mainly identical to the first exemplary embodiment of the ultrasonic transducer 1. Identical features of the two exemplary embodiments are not described again to avoid repetition. Differences between the two embodiments will be described below.

In contrast to the first exemplary embodiment, in the third exemplary embodiment the electrodes 14A and 14B protrude noticeably from the lower side 11. Likewise, the contact area 9A and 9B protrude noticeably from the inner side of the carrier 3A.

To achieve this, the electrodes 14A and 14B and the contact areas 9A and 9B are reinforced during the manufacturing process. For example, the electrodes or the contact areas are reinforced by sputtering chromium, nickel, silver or copper. Alternatively, the electrodes and the contact areas can be reinforced by electroplating or electroplating, for example.

In the third embodiment, the adhesive connection 15 is exclusively formed around the non-protruding surfaces of the lower side 11 and the inner side of the carrier 3A. In contrast, no adhesive connection is formed between the protruding surfaces of the electrodes 14A, 14B and the contact areas 9A, 9B. This is because the adhesive is displaced when the piezoelectric element 10 and the carrier 3 are pressed together.

A fourth exemplary embodiment of the ultrasonic transducer 1 is described below. The fourth exemplary embodiment of the ultrasonic transducer 1 is substantially similar to the first exemplary embodiment of the ultrasonic transducer 1. Identical features of the two exemplary embodiments are not described again to avoid repetition. Differences between the two embodiments will be described below.

In the fourth embodiment, the first contact point 9A is electrically connected to the electronics 17 via the first conductor track 8A. Instead of the second conductor track, the container 2, which is made of electrically conductive aluminum, itself acts as an electrical conductor between the second contact point 9B and the electronics 17, as shown in FIG. 7. For this purpose, the electrically insulating anodised layer 2A, is interrupted at a first breakthrough point at the second contact point 9B and at a second breakthrough point in the wall 4, which is opposite the second connection point 17B of the lid 16. The electrically conductive container 2 can therefore be electrically contacted at these points. In this embodiment, the carrier 3 and the wall 4 form a coherent and electrically conductive container 2.

At the first breakthrough point, the second contact point 9B is formed, for example, by means of an electrically conductive metal layer made of chromium, copper, silver or nickel. The metal layer can be applied, for example, by sputtering, electroplating, inkjet printing or screen printing. The second contact point 9B electrically connects the electrically conductive container 2 and the second electrode 14B.

A further electrically conductive layer, for example a metal layer or a conductive adhesive layer, is applied to the second breakthrough point in the wall 4, which electrically connects the electrically conductive container 2 and the second connection point 17B of the electronics 17.

In alternative embodiments, the second breakthrough point is formed at any location in the wall 4. A second conductor track 8B is then applied to the inner side of the wall 4A from the second breakthrough point to the second connection point 17B.

A fifth embodiment is mainly identical to the fourth embodiment and has the following differences.

The electrically conductive container 2, which acts as the second conductor track, is not in contact with the second electrode 14B. The anodised layer 2A on the inner side of the carrier 3A is not interrupted at the point where the second contact area 9B is applied.

In the fifth embodiment, the container 2 and the second contact area 9B form an electrical capacitor 21. Via the capacitor 21, the applied AC circuit can be closed capacitively (AC capacitor), as shown in FIG. 8.

Thus, a separate AC capacitor in the electronics 17 can be dispensed with and the apparatus design of the ultrasonic transducer 1 is simplified. Furthermore, this embodiment enables electrical contacting of the container 2 with ground.

In a further embodiment, the second contact point 9B may be dispensed with entirely. The capacitor is then formed between the container 2 and the second electrode 14B.

In the following, a sixth exemplary embodiment of the ultrasonic transducer 1 is described that is not explicitly shown in the drawings. The sixth exemplary embodiment of the ultrasonic transducer 1 is substantially similar to the first exemplary embodiment of the ultrasonic transducer 1. Identical features of the two exemplary embodiments are not described again to avoid repetition. Differences between the two embodiments will be described below.

In contrast to the first embodiment, the sixth embodiment has a container 2 made of non-conductive material. The non-conductive material is, for example, a liquid crystal polymer (LCP). Alternatively, the non-conductive material may comprise another suitable material or a mixture of different materials. Examples include, in particular, polymers or composite materials that are also commonly used for printed circuit boards, for example FR-4 composite material.

The container 2 can have means connected to the electronics 17 which ensures sufficient shielding from radiated electromagnetic interference (Faraday shielding) despite the non-conductive container material. For example, the container may contain internal electrode structures or metal meshes (copper network) which are suitably connected to ground with the electronics 17.

In a seventh embodiment not explicitly shown in the drawings, the electronics 17 may be wholly or partially arranged within the container 2 or form the container 2. For example, conductor traces, passive electrical components, active electrical components, or electrical circuits may be arranged in the container material.

An eighth exemplary embodiment, which is not explicitly shown in the drawings, is substantially similar to the sixth exemplary embodiment. In contrast to the sixth exemplary embodiment, at least one conductor trace is structured inside the container 2.

The container 2 consists here, for example, of LCP doped with 4% electrically conductive metal particles. The electrically conductive metal particles can be structured inside the container 2 so that they form a conductor trace 8B between the contact point 9B and the associated connection point 17B of the electronics 17, which is not exposed at the surface. At the contact point or at the connection point, the conductor trace 8A is structured as far as the inner side of the carrier 3A or as far as the inner side of the wall 4A and is thus exposed there. One possible method for forming the conductor trace 8B is to fuse the conductive metal particles using a laser-based process.

Conductive material can then be applied to the inside of the carrier 3A at the point where the conductor trace 8B is exposed, by chemical processes such as electroplating or galvanization, to form the electrical contact area 9B. The patterned, electrically conductive surface of the conductor trace 8B can serve as a seed layer for this purpose. Similarly, an electrical contact area can be formed at the location of the inner side of the wall 4A where the conductor trace 8B is exposed.

The electrically non-conductive layer of the container 2 over the structured conductor trace 8B is removed, for example, and the metal particles are exposed and fused together. Further electrically conductive material can be applied.

In all other respects, the ultrasonic transducer 1 of the eighth embodiment may be formed analogously to the fourth embodiment.

Furthermore, the formation of AC capacitors as in the fifth embodiment is also possible if the conductor trace 8B, inside the container 2, is not patterned up to the inner side of the carrier 3A, so that a non-conductive layer of the container 2 remains between the conductor trace 8B and the inner side of the carrier 3A.

In the eighth embodiment, in contrast to the fifth embodiment, two separate conductor traces 8A and 8B can be structured in the container 2, since the container 2 itself is not conductive. In this case, no further conductor traces applied to the inner side of the carrier 3A or the inner side of the wall 4A are necessary.

Furthermore, in the present embodiment, two AC capacitors may be formed, one each between first electrode 14A and first conductor track 8A and one between second electrode 14B and second conductor track 8B.

A ninth exemplary embodiment of the ultrasonic transducer 1, which is not explicitly shown in the drawings, is described below. The ninth exemplary embodiment of the ultrasonic transducer 1 is mainly identical to the first exemplary embodiment of the ultrasonic transducer 1. Identical features of the two exemplary embodiments are not described again to avoid repetition. Differences between the two embodiments will be described below.

In contrast to the first embodiment, the ninth embodiment does not feature an adhesive connection 15 between the piezoelectric element 10 and the carrier 3. Rather, the electrodes 14A and 14B are directly bonded to the corresponding contact areas 9A and 9B, respectively.

This is achieved, for example, by first forming the electrode 14A, electrode 14B, the contact area 9A, and the contact area 9B by sputtering. In a second step, the piezoelectric element 10 and the inner side of the carrier 3A are then pressed together so that the first electrode 14A rests on the first contact area 9A and the second electrode 14B rests on the second contact area 9B. The entire assembly described is then heated so that an electrical and mechanical material connection is formed between the contact areas and the electrodes. In this way, a particularly good coupling can be achieved between the piezoelectric element 10 and the carrier 3. The piezoelectric element 10 is thus also attached to the carrier 3.

The ultrasonic transducer 1 according to any of the embodiments may include additional components and elements beyond those previously shown. An exemplary detailed structure of such an ultrasonic transducer 1 is shown in FIGS. 9 and 10.

The double-cylinder-shaped container 2 has a cylindrical lower part with a smaller diameter and a cylindrical upper part with a larger diameter. The lower part is adjacent to the support 3, and the upper part is adjacent to the lid 16. The lower and upper parts are connected to each other by a connecting surface oriented parallel to the support 3 and the lid 16.

The wall 4 of the lower part of the container 2 is externally covered with a vibration damping component 22. The connecting surface between the lower and the upper part of the container 2 is provided with adhesive material 23 from the outside. The piezoelectric element 10 is fixed on the support 3 inside the container 2. Above this, the damping element 24, which fills most or all of the cavity 6 of the container 2, is arranged. The damping element 24 can already be manufactured and hardened before the ultrasonic transducer is assembled.

Depending on the embodiment, electrical contact areas 9A/9B and an adhesive 15 may be arranged between the carrier 3 and the piezoelectric element 10. The contact areas 9A/B can be part of the conductor traces 8A/8B (see FIG. 10).

The connecting surface between the upper and lower portions of the container 2 is thicker than the remainder of the container 2. The reinforced connecting surface is designed to be used as support surfaces on a fixture, scaffold, or support structure in an application.

The carrier 3, which is also used as a membrane, is thinner than 1 mm. On the one hand, the carrier 3 must be elastic enough not to strongly hinder the deflection of the piezoelectric element 10. On the other hand, the carrier 3 must have a certain stability so that it will not be damaged when an external force is applied, such as when it is irradiated with water for cleaning. An advantageous compromise was found with a thickness of the carrier 3 of less than 1 mm and more than 0.2 mm.

The walls are at least 1.5 times as thick as the carrier 3, but should be thicker than 3 times the thickness of the carrier 3 if possible. Such a thick wall thickness is suitable to reduce the transmission of vibrations of the carrier 3 or the membrane to the connecting surface between the upper and lower parts of the container 2. Since the connecting surface may be a supporting surface of the ultrasonic transducer 1 to a mounting, vibrations and deflections should be avoided especially at these connecting surfaces. Otherwise, vibrations may be transmitted to an adjacent fixture that is part of the application. The transmitted vibrations can in turn be reflected and therefore be falsely detected in the ultrasonic transducer 1 as a phantom signal. A wall thickness that is at least 1.5 times the thickness of the membrane reduces the transmission of vibrations from the carrier 3 to other parts of the container 2, thus helping to pervent this problem.

The lid 16 is a printed circuit board and has a digital I/O interface 25 on one side facing outward.

The digital I/O interface 25 is not only used to communicate with the outside, but also to supply the electronics 17 and thus the piezoelectric element 10 with electricity. The electronics 17 are arranged on one side of the lid 16, which faces into the interior of the container 2.

The arrangement of the digital I/O interface 25 on the lid 16 enables a compact design of the ultrasonic transducer 1 and simple contacting, since no further connections need to be considered. In contrast to analog interfaces, a digital I/O interface 25 has a high tolerance with respect to interference signals, which may come from nearby electric motors, for example. For example, the interface can also be implemented with an FFC connector. This provides a debug interface via its eight contacts, which offers a variety of readout options that can be particularly advantageous for developers and for more complex applications. As a particularly simple alternative, a 2- or 3-wire interface can be used as an interface. These are the most cost-effective interfaces compared to the previously mentioned alternatives. Simple pin headers provided with two to eight pins are also possible as an interface for the ultrasonic transducer 1.

The lid 16 is mechanically attached to the container 2 by an annular, elastic adhesive connection 18. The annular, elastic adhesive connection 18 is not electrically conductive. The annular, elastic adhesive connection 18 is attached to the side of the lid 16 facing into the interior of the container 2, between the lid 16 and the container 2.

Additionally or alternatively, electrically conductive elastic adhesive connections 19 are provided between the electronics 17 and the container 2, electrically connecting the connection points of the electronics 17 and the conductor traces 8A and 8B. The electrically conductive elastic adhesive connections 19 can replace sections of the annular elastic adhesive connection 18 (cf. FIG. 10).

In addition, a second annular elastic adhesive connection 26 may be provided between the lid 16 and the container 2 on the side of the lid 16 facing outward. The second annular, elastic adhesive connection 26 seals the container 2 to the outside. The second annular, elastic adhesive connection 26 may have the same properties as the first annular, elastic connection 18 or other properties.

### LIST OF REFERENCE SIGNS

1 ultrasonic transducer
2 container
2A anodised layer
3 Carrier, bottom
3A inner side of the carrier
4 wall
4A inner side of the wall
5 opening
6 cavity
7 insulation layer
8 conductor trace
8A first conductor trace
8B second conductor trace
9 contact area
9A first contact area
9B second contact area
9C recesses
9D elevation
10 piezoelectric element
11 lower side
12 upper side
13 side surface
14 electrodes
14A first electrode
14B second electrodes
15 adhesive connection
16 lid
17 electronics
17A first connection point
17B second connection point
18 first annular, elastic adhesive connection
19 electrically conductive, elastic adhesive connections
19A First electrically conductive elastic adhesive connection
19B second electrically conductive elastic adhesive connection
20 conductive particles
21 AC capacitor
22 vibration damping component
23 adhesive material
24 damping element
25 I/O interface
26 second annular elastic adhesive connection

1. An ultrasonic transducer comprising:
a carrier with conductor traces; and
a piezoelectric element with electrodes, wherein the piezoelectric element has a contact side which is fixed on the carrier, and wherein the conductor traces and the electrodes are electrically coupled via the contact side of the element.

2. An ultrasonic transducer comprising:
a container with a bottom designed as a carrier, a wall and an installation opening that is closable with a lid;
electronics integrated in the container and/or in the lid;
a piezoelectric element having a contact side fixed on the carrier; and
conductor traces electrically connecting electrodes of the piezoelectric element and connection points of the electronics.

3. The ultrasonic transducer according to claim 2, wherein the conductor traces and the electrodes are electrically coupled via the contact side of the piezoelectric element.

4. The ultrasonic transducer according to claim 2, wherein the ultrasonic transducer is configured such that the electrodes are differently polarized during operation.

5. The ultrasonic transducer according to claim 2, wherein the ultrasonic transducer is configured to apply a voltage between the electrodes during operation.

6. The ultrasonic transducer according to claim 2, wherein the lid can be fixed to the container by means of an electrically conductive lid adhesive and the electronics integrated in the lid can be electrically contacted with the conductor traces.

7. The ultrasonic transducer according to claim 6, wherein a damping element is arranged in a cavity in the container between the carrier with the piezoelectric element and the lid.

8. The ultrasonic transducer according to claim 2, wherein the electrodes on the piezoelectric element and the connection points of the electronics are electrically connected exclusively by the conductor traces.

9. The ultrasonic transducer according to claim 2, wherein the piezoelectric element is a piezoelectric disk.

10. The ultrasonic transducer according to claim 2, wherein the electrodes electrically contact the conductor traces of the carrier.

11. The ultrasonic transducer according to claim 2, wherein the electrodes comprise a first electrode and a second electrode, wherein the first electrode is arranged areally on the contact side of the piezoelectric element and wherein the second electrode is arranged substantially areally on a side of the piezoelectric element opposite to the contact side and furthermore, wherein parts of the second electrode are arranged on a side surface and on the contact side of the piezoelectric element.

12. The ultrasonic transducer according to claim 2, wherein the contact side of the piezoelectric element is fixed to the support by means of a support adhesive.

13. The ultrasonic transducer according to claim 12, wherein the carrier adhesive is electrically insulating.

14. The ultrasonic transducer according to claim 13, wherein the electrodes and the conductor traces have rough surfaces that are spaced such that the electrodes and the conductor traces are in direct contact.

15. The ultrasonic transducer according to claim 13, wherein portions of the electrodes and the conductor traces are exposed to their surroundings and are in direct contact with each other.

16. The ultrasonic transducer according to claim 13, wherein the electrodes and the conductor traces are capacitively coupled.

17. The ultrasonic transducer according to claim 12, wherein the carrier adhesive means is anisotropically electrically conductive, so that the carrier adhesive means is formed as an electrical contact between the electrodes and the conductor traces and at the same time different electrodes are insulated from each other.

18. The ultrasonic transducer according to claim 2, wherein the conductor traces are arranged on an inner surface of the container.

19. The ultrasonic transducer according to claim 2, wherein the conductor traces are integrated inside the container.

20. The ultrasonic transducer according to claim 2, wherein the container has rotational symmetry.

21. The ultrasonic transducer according to claim 20, wherein the container is cylindrical, conical or frustoconical.

22. The ultrasonic transducer according to claim 2, wherein the container comprises means interconnected with the electronics to provide shielding of radiated electromagnetic disturbances in the form of Faraday shielding.

23. The ultrasonic transducer according to claim 22, wherein a metallic coating is applied to an inner and/or outer side of the container as means for Faraday shielding.

24. The ultrasonic transducer according to claim 22, wherein internal electrode structures or metal meshes such as copper meshes are applied to an inner side of the container as means for Faraday shielding.

25. The ultrasonic transducer according to claim 2, wherein a protective mechanical coating is applied to the outside of the container.

26. An ultrasonic transducer comprising a container with an installation opening which can be closed by a lid that has integrated electronics, wherein the lid can be fixed to the container by means of an electrically conductive lid adhesive and the electronics can be electrically contacted with conductor traces of the container.

27. A method of manufacturing an ultrasonic transducer, comprising the steps:
a) providing a container which can be closed by a lid that has integrated electronics and the container having an installation opening that comprises a bottom designed as a support and conductor paths; and
b) fixing a piezoelectric element in the container on the support so that electrodes arranged on the piezoelectric element are electrically connected via the conductor traces to connection points of the electronics.

28. The method of manufacturing an ultrasonic transducer according to claim 27, wherein step b comprises:
fixing the piezoelectric element so that the electrodes are electrically coupled to the conductor traces; and
closing the installation opening with the lid, wherein connection points of the electronics are electrically coupled to the conductor traces so that the electronics are electrically connected to the electrodes in a wireless manner.

29. The method of manufacturing an ultrasonic transducer according to claim 27, further comprising:
inserting a damping element that fills the container between the piezoelectric element and the lid.
